(19) United States
(12) Patent Application Publication
(10) Pub. No.: US 2006/0213423 A1
(43) Pub. Date: Sep. 28, 2006

(54) Method for producing a composite material that can be used as a photonic crystal

(76) Inventors: Christian Goebbert, Riegelsberg (DE); Frank Meyer, Saarbruecken (DE); Ralph Nonninger, Saarbruecken (DE)

Correspondence Address: NATH & ASSOCIATES, 112 South West Street, Alexandria, VA, 22314, US

(21) Appl. No.: 10/553,910

(22) PCT Filed: Apr. 23, 2004
(86) PCT No.: PCT/EP04/04295

§ 371 Date: Jan. 24, 2006

(30) Foreign Application Priority Data
Apr. 23, 2003 (DE) 103 18 480.5

(51) Int. Cl. H01L 21/322

(52) U.S. Cl. 117/2

(57) ABSTRACT

The invention relates to a process for producing a composite material which has properties permitting it to be used as what is known as a “photonic crystal”. The process is a template-based process. Moreover, the invention relates to the composite materials produced by the process and to the use of these materials.

The invention relates to a process for producing a composite material, to the composite material produced by the process and uses in which this composite material is employed as what is known as a photonic crystal.

Photonic crystals represent the optical analog of semiconductors and are able to control photons (particles of light) in the same way as semiconductors control electrons. In semiconductor materials, electron waves propagate in periodic potential predetermined by the crystal atoms. A band structure with a band gap is formed, permitting or blocking certain energy states for electrons. The position and extent of the band gap can in this case be varied by targeted introduction of defects (doping).

Photonic crystals are composite materials (the term “composite material” is to be understood as meaning a combination of a plurality of materials) with a periodically varying refractive index, which influences the propagation of electromagnetic waves in a similar way to the situation for electron waves in a semiconductor. In photonic crystals, multiple scattering at periodically arranged “dielectric atoms” lead to the formation of an optical band structure and therefore to the generation of what is known as a photonic band gap. This band gap means that light of a certain wavelength can no longer propagate unimpeded or that only certain wavelengths can pass through the photonic crystal.

Despite extensive analogies between electronic waves in semiconductors and electromagnetic waves in photonic crystals, there are also significant differences. For example, electrons are described by a scalar alternating field, whereas the electromagnetic field has a vectorial character. The fact that these differences tend to have an adverse effect on the formation of photonic band gaps can be imagined from the small number of photonic crystals which occur naturally. Out of the wide range of optical phenomena, only the shimmering effects of opals and a few crystallites on butterflies wings are attributable to naturally occurring photonic crystals.

By drilling thin channels into a dielectric (silicon), Yablonovitch et al. 1991 [Phys. Rev. Lett. 67, 2295 (1991)] were for the first time able to produce a photonic crystal (Yablonovite) with a complete band gap in the microwave region. This is a scientific milestone, but a band gap in the microwave region is of no industrial significance. Photonic crystals are only industrially significant if it is possible to use these crystals to switch visible light, i.e. if the photonic crystal has a band gap in the visible spectral region (400-750 nm). The most significant drawback of the Yablonovite produced by Yablonovitch is that it cannot readily be miniaturized, since, for example for crystallites in the visible spectral region, it would be necessary to drill accurate, three-dimensionally arranged channels with a diameter of less than 1 μm into dielectrics. Since this is not technically feasible, new production methods need to be developed for photonic crystals in the visible frequency region.

A further option for the production of photonic crystals is to process dielectrics, such as silicon, with the aid of lithographic, mask-aided processes. Nowadays, these processes are used for two-dimensional patterning in the electronics industry. However, the lithography process can only be used with very considerable difficulty for three-dimensional patterning and furthermore entails a high outlay on equipment and a large number of process steps. The process is uneconomical for the production of photonic crystals. In practice, at present all efforts around the world are concentrated on what are known as colloidal processes.

One known example of the production of three-dimensional structures using colloidal processes is the production of synthetic opals. Natural opals consist of three-dimensionally structured, uniform SiO₂ particles, which leads to characteristic color appearances. They can be produced by SiO₂ particles being produced synthetically and transferred to an aqueous solution. After concentration and removal of foreign ions, the SiO₂ particles self-organize themselves to form three-dimensional structures (the term self-organization is to be understood as meaning a form of organization in which a two-dimensional or three-dimensional structure can be obtained substantially without external influences or in which a structure of this type can be attributed to the voluntary arrangement of the structure-forming elements of the system). Synthetic opals are obtained after a heat treatment.

This self-organization can now also be exploited to produce photonic crystals. Starting from synthetically produced SiO₂ particles, these particles are first of all coated with a second material (usually titanium alkoxide). The result is SiO₂ particles which are coated with a TiO₂ precursor. After self-organization of the coated SiO₂ particles, a three-dimensional structure is obtained. The SiO₂ particles are removed from this structure by means of hydrofluoric acid, and the TiO₂ is crystallized by calcining. What remains is a three-dimensional, periodic network of TiO₂ (the former interstices between the three-dimensionally arranged SiO₂ particles), which surrounds hollow spheres of air (where the SiO₂ spheres were previously present). The resulting three-dimensional structure is therefore the inverse of the structure which resulted from the self-organization of the coated SiO₂ particles.

A composite material (titanium dioxide/air) produced in this way has a refractive index difference from air to TiO₂ of approx. 1.3. A refractive index difference of greater than two units is generally required to form a complete photonic band gap in the visible spectral region. This is not achieved here. This problem also occurs if a similar process is used but latex, polymethyl methacrylate (PMMA) or butyl acrylate spheres are used instead of SiO₂ particles.

There is therefore a demand for a process which allows the production of composite materials with three-dimensional structures with a periodically varying refractive index, in which the refractive index difference, as described, should be sufficiently high for it to be possible to form a complete photonic band gap in the visible spectral region.

Accordingly, the invention is based on the object of providing a process for producing a composite material having the required properties which represents a solution to the problems discussed.

To achieve this object, the invention proposes a process having the features of claim 1. Preferred embodiments of the process according to the invention as described in claim 1 are given in the dependent claims 2 to 21. The subject matter of the invention is also formed by composite materials having the features of the independent claims 22 and 23, preferred embodiments of which are described in claims 24 to 30. Another subject of the invention is the use of the composite material according to the invention as described in the independent claim 31. The wording of all the claims is hereby incorporated by reference in the content of the present description.

The process according to the invention is distinguished by the fact that a structure-directing building block, known as a template, which predetermines the structure of the composite material to be produced in the form of a three-dimensional template, is used. Unlike in the case of the above-described production of synthetic opals, however, the process does not lead to a three-dimensionally inverse-structure. Instead, what is produced is a composite material with a structure which substantially corresponds to a three-dimensional copy of the template.

At least two materials with different refractive indices occur in a substantially periodic sequence along all three spatial directions in the composite material.

It is preferable for the structure of the composite material to be composed of three-dimensionally arranged, in particular substantially spherical particles. The particles are preferably all of substantially the same size.

Furthermore, it is preferable for the composite material to include two materials whereof the refractive index differs by at least two units from one another (Δn≧2). As has already been stated, this is generally a required precondition for it to be possible for a complete photonic band gap in the visible spectral region to be formed.

A process according to the invention preferably includes a plurality of successive individual steps. First of all, what is known as a primary template is produced (step a)), this primary template having a structure made up of three-dimensionally arranged, preferably substantially spherical particles with cavities (the abovementioned interstices) between these particles. In a further step (b)), the cavities of the primary template are filled with a curable material. After the curable material has been cured, the primary template is removed (step c)). The result is a structure which represents a three-dimensional negative of the structure of the primary template, referred to as the secondary template. This structure consists of the cured material at the locations of the previous interstices and substantially spherical cavities. These cavities in the secondary template are then filled with at least one precursor of an inorganic oxide (step d)). In a further step (e)), the precursor is converted into the inorganic oxide. After it has been hydrolyzed, the precursor is preferably converted into the oxide by a pressure treatment in combination with a heat treatment. However, it is also conceivable for the conversion to be carried out solely by means of a pressure treatment or solely by means of a heat treatment. Then, the secondary template is removed (step f)). This produces a three-dimensional copy of the primary template. The structure which then results includes substantially spherical oxide particles, like the primary template with cavities between the particles. This is preferably a crystalline or at least crystal-like structure, for example in the form of a sphere packing.

It is particularly preferable for the oxide particles of the structure which results from step f), in a further step (g)), to be substantially completely covered with a metal, in particular with Cu, Ag, Au, Pt or Pd, or an alloy of these metals. The covering of the oxide particles with the metal shell produces a composite material (metal oxide/metal) with generally a high refractive index difference. By way of example, the refractive index difference between TiO₂ and silver is well above two units.

The refractive index difference can be varied as desired over a wide range by setting the thickness of the metal layer, varying the metal oxide (e.g. TiO₂, ZrO₂ or also Al₂O₃) and/or the metal deposited thereon.

The cavities in the structure which results from step g) are preferably at least partially filled with the metal used to cover the oxide particles. It is equally preferable for the cavities to be completely filled with the metal.

The primary template is produced in particular by a self-organization route as explained in the introduction with reference to the example of the production of synthetic opals. However, production by way of a different conventional shaping process known to the person skilled in the art, such as for example pressing, electrophoresis, slip casting or others, is also conceivable.

The primary template is in particular a colloidal SiO₂ crystal template. In particular templates in which the three-dimensionally arranged, preferably substantially spherical particles are arranged as densely as possible, for example in the form of a sphere packing, are preferred.

The primary template is preferably removed by chemical or physical dissolution, preferably using a basic solution, in particular using sodium hydroxide solution. It is equally preferable for the dissolution to be carried out using an acidic solution, in particular using hydrofluoric acid.

The curable material with which the cavities in the primary template are filled in step b) is preferably a polymerizable compound or composition, in particular methyl methacrylate. In the case of methyl methacrylate, polymethyl methacrylate results from the curing.

In step d), the precursor used is preferably an alkoxide oligomer of a metal preferably selected from the group consisting of Al, Zr, Fe or Ti, in particular titanium alkoxide oligomer. In a corresponding way, Al₂O₃, ZrO₂, Fe₂O₃ or TiO₂ preferably results from the conversion of the precursor into the inorganic oxide.

It is preferable for the inorganic oxide to be doped, preferably with Al, Ga, Gd, Sn and/or Ge. The doped inorganic oxide is produced in particular from a single-source precursor. This allows the crystal structure to be tailored at molecular level, and consequently allows very homogeneous doping. It is in this way possible to control phase composition (e.g. anatase/rutile) and disorders (electronic properties) in a targeted way, so that the band gap of the photonic crystal can be influenced in a targeted way. The doping results in a dual-function composite material. A material of this type has a variable electronic band gap and a photonic band gap. During production, therefore, it is possible to control electronic properties and photonic band gap of the composite material to be produced as a function of the precursor used.

However, the doping can be effected not only via a single-source precursor (in this case matrix material and doping material are already present in the form of a compound). It is also possible to use two precursors (matrix material and doping material as two compounds). However, this usually produces less homogeneous doping.

The heat treatment involved in converting the precursor into the inorganic oxide in step e) is preferably carried out at temperatures of <250° C., in particular between 180° C. and 250° C.

The pressure treatment in accordance with step e) is carried out in particular at pressures of >1 bar, in particular between 2 bar and 5.0 bar. The choice of a low pressure generally leads to the pressure treatment taking more time.

The pressure treatment and/or heat treatment in the context of the process according to the invention particularly advantageously results in the formation of a solid structure of an inorganic oxide, for example a TiO₂ structure. Specifically, a structure of this type is formed directly without a calcining step being required. This is important in particular in the case of doped materials, since it means that there is no segregation of the doping at the grain boundaries, as is otherwise customary. This gives considerable advantages over conventional processes.

In step f), the secondary template is removed by a chemical or thermal route. It is preferable for it to be removed by chemical or physical dissolution, preferably by means of an organic solvent, in particular by means of acetone, tetrahydrofuran, ethyl acetate and/or dimethylformamide.

It is preferable for the metal oxide to be covered with a metal layer by a wet-chemical route. For example, starting from a metal salt solution, at least one metal can be applied as a shell to the particles to be covered, by reduction, for example by a radiation-induced redox reaction. In this case, it is very easy to control the thickness and homogeneity of the metal layer. However, it is also possible for metal oxide particles to be coated directly by reacting the metal oxide particles with a precious metal sol.

The resulting particles of the structure of the composite material are preferably what are known as core-shell particles. Their core particularly preferably substantially comprises TiO₂ and their shell particularly preferably substantially comprises silver.

It is preferable for a structure which results from a process according to the invention, as its particles, to include nanoparticles with a particle size of <500 nm, preferably <250 nm.

The composite materials which are produced by a process according to the invention also form the subject of the present invention.

As will already be clear from the description of the process, a composite material according to the invention preferably has a structure of three-dimensionally arranged, substantially spherical particles, with at least two materials with different refractive indices occurring in a periodic sequence along all three spatial directions.

It has likewise already been mentioned that the substantially spherical particles are preferably what are known as core-shell particles, the core of which consists in particular of an inorganic oxide, preferably of Al₂O₃, ZrO₂, TiO₂ and/or Fe₂O₃, and the shell of which is preferably metallic, preferably formed from Cu, Ag, Au, Pt or Pd or an alloy of these metals.

In a particularly preferred composite material, the core of the core-shell particles substantially comprises TiO₂ and the shell substantially comprises silver.

It is equally preferable for the core of a composite material according to the invention to be doped, in particular with Al, Ga, Gd, Sn and/or Ge. A composite material in which the core is produced from a single-source precursor and has a particularly homogeneous doping is particularly preferred.

Composite materials according to the invention in particular include two materials whereof the refractive index differs by at least two units from one another (Δn≧2). As has already been described, composite materials of this type can form a complete photonic band gap in the visible spectral region.

Depending on their properties, composite materials according to the invention can be used for a wide range of applications, in particular as a photonic crystal preferably in high-power miniature lasers, optical fibers, ultra-white pigments, RF antennas and reflectors, LEDs or in photonic circuits.

Further features of the invention will emerge from the following description of preferred embodiments in conjunction with the subclaims. In this context, the individual features can in each case be realized on their own or as a combination of a plurality of these features with one another in an embodiment of the invention.

### EXAMPLE 1

A gel is produced from hydrolysis of 38.0 g of TEOS (tetraethoxysilane) in 100 g of ethanol with 34.2 g of water and 4.0 g of acetic acid. Gradual removal of the solvent in a vessel leads, in a known way, depending on parameters such as temperature, pH and catalyst, to the formation of a three-dimensional structure of regularly arranged SiO₂ spheres with a particle size of between 5 nm and 500 nm, preferably 250 nm. In the next step, the gaps between the SiO₂ spheres are filled with methyl methacrylate, which is then polymerized to form polymethyl methacrylate (PMMA). After complete polymerization, the SiO₂ spheres are dissolved by 2 N sodium hydroxide solution at 35° C. The holes formed in this way are filled with a titanium alkoxide oligomer, which may be doped with, for example, Al, Ga, Gd, Sn and/or Ge and has been produced as a single-source precursor. In a further step, the alkoxide is hydrolyzed. This is followed by a treatment in a high-pressure autoclave for a period of 2 hours at a temperature of approx. 230° C. and a pressure of approx. 30 bar, producing substantially spherical TiO₂ particles. Then, the PMMA is removed by being dissolved using acetone. In a final step, the spherical TiO₂ particles are covered with a metal layer of Ag by reduction using a wet-chemical route.

1. A process for producing a composite material, in which at least two materials with different refractive indices occur in a substantially periodic sequence along all three spatial directions, the structure of the composite material being produced using at least one structure-directing building block in the style of a template as a three-dimensional copy thereof.

2. The process as claimed in claim 1, wherein the structure of the composite material is composed of three-dimensionally arranged, preferably substantially spherical particles.

3. The process as claimed in claim 1 wherein the composite material includes two materials whereof the refractive index differs by at least two units from one another (Δn≧2).

4. The process as claimed in claim 1, comprising the following steps:
a) producing a primary template, which has a structure made up of three-dimensionally arranged, preferably substantially spherical particles with cavities (interstices) between these particles,
b) filling the cavities of the primary template with a curable material and curing the curable material,
c) removing the primary template in order to produce a structure which represents a three-dimensional negative of the structure of the primary template,
d) filling the cavities in the secondary template with at least one precursor of an inorganic oxide,
e) hydrolyzing the precursor and converting it into the inorganic oxide by means of a pressure and/or heat treatment,
f) removing the secondary template to produce a three-dimensional copy of the primary template composed of oxide particles.

5. The process as claimed in claim 4, wherein the oxide particles of the structure which results from f) are substantially completely covered with a metal, in particular with Cu, Ag, Au, Pt or Pd, or an alloy of these metals.

6. The process as claimed in claim 4, wherein the cavities in the resulting structure are at least partially filled with the metal.

7. The process as claimed in claim 4, wherein the primary template is produced by a self-organization route.

8. The process as claimed in claim 4, wherein the primary template is a colloidal SiO₂ crystal template.

9. The process as claimed in claim 4, wherein the primary template is removed by chemical or physical dissolution, preferably using a basic solution, in particular using sodium hydroxide solution, or using an acidic solution, in particular using hydrofluoric acid.

10. The process as claimed in claim 4, wherein the curable material is a polymerizable compound or composition, in particular methyl methacrylate.

11. The process as claimed in claim 4, wherein the inorganic oxide is Al₂O₃, ZrO₂, Fe₂O₃ or TiO₂.

12. The process as claimed in claim 4, wherein the precursor is preferably an alkoxide oligomer of a metal preferably selected from the group consisting of Al, Zr, Fe or Ti.

13. The process as claimed in claim 4, wherein the inorganic oxide is doped, preferably with Al, Ga, Gd, Sn and/or Ge.

14. The process as claimed in claim 13, wherein the doped inorganic oxide is produced from a single-source precursor.

15. The process as claimed in claim 4, wherein the heat treatment in accordance with step e) is carried out at temperatures of <250° C., in particular between 180° C. and 250° C.

16. The process as claimed in claim 4, wherein the pressure treatment in accordance with step e) is carried out at pressures of >1 bar, in particular between 2 bar and 50 bar.

17. The process as claimed in claim 4, wherein the secondary template is removed by chemical or physical dissolution, preferably by means of an organic solvent, in particular by means of acetone, ethyl acetate, tetrahydrofuran and/or dimethylformamide.

18. The process as claimed in claim 5, wherein the covering of the oxide particles with a metal is carried out by a wet-chemical route.

19. The process as claimed in claim 1, wherein the resulting particles of the structure of the composite material are core-shell particles.

20. The process as claimed in claim 19, wherein the core of the core-shell particles substantially comprises TiO₂ and the shell substantially comprises silver.

21. The process as claimed in claim 2, wherein the particles are nanoparticles with a particle size of <500 nm, preferably <250 nm.

22. A composite material, produced by the process as claimed in claim 1.

23. A composite material, producible by the process as claimed in claim 1.

24. The composite material as claimed in claim 22, wherein it has a structure of three-dimensionally arranged, substantially spherical particles, and at least two materials with different refractive indices occur in a periodic sequence along all three spatial directions.

25. The composite material as claimed in claim 24, wherein the substantially spherical particles are what are known as core-shell particles.

26. The composite material as claimed in claim 25, wherein the core is an inorganic oxide, preferably Al₂O₃, ZrO₂, and/or Fe₂O₃.

27. The composite material as claimed in claim 25, wherein the shell is metallic, preferably form from Cu, Ag, Au, Pt or Pd or an alloy of these metals.

28. The composite material as claimed in claim 25, wherein the core of the core-shell particles substantially comprises TiO₂ and the shell substantially comprises silver.

29. The composite material as claimed in claim 25, wherein the core is doped, preferably with Al, Ga, Gd, and/or Ge.

30. The composite material as claimed in claim 24, wherein it includes two materials whereof the refractive index differs by at least two units from one another (Δn≧2).

31. (canceled)
